(19) United States
(12) Patent Application Publication
(10) Pub. No.: US 2024/0321376 A1
(43) Pub. Date: Sep. 26, 2024

(54) Sense Amplifier Scan Capture Circuit with Reduced Sense Amplifier Offset

(71) Applicant: QUALCOMM Incorporated, San Diego, CA (US)

(72) Inventors: Debarghya DUTTA, Kolkata (IN); Ramakoti NIMMAKAYALA, Bangalore (IN); Rahul SAHU, Bangalore (IN)

(21) Appl. No.: 18/123,852

(22) Filed: Mar. 20, 2023

(51) Int. Cl. G11C 29/32; G11C 7/06; G11C 29/12

(52) U.S. Cl. CPC G11C 29/32; G11C 7/065; G11C 29/1201; G11C 2029/3202

(57) ABSTRACT

A memory is provided with scan path coupled to sense amplifier output nodes. The scan path include a clocked latch that latches a data-in signal responsive to a clock signal during a scan operation to the memory. The clocked latch is not clocked during a read operation to the memory. To prevent a binary transition of the data-in signal from affecting the read operation, the scan path includes at least one blocking logic gate coupled between the clocked latch and the sense amplifier output node.

### TECHNICAL FIELD

This application relates to memories, and more particularly to a sense amplifier scan capture circuit with reduced sense amplifier offset.

### BACKGROUND

A system-on-chip (SoC) such as used to form the “brain” for a smartphone will generally have millions of transistors distributed across a chip substrate. A substantial proportion of these transistors (e.g., up to 80% of the semiconductor die space) is dedicated to embedded memories. An SoC will thus typically have thousands of embedded memories. The speed, power consumption, and accuracy of the embedded memories is therefore a major factor in SoC design and manufacture, making it important to verify the operation of the embedded memories through various scan operations.

### SUMMARY

In accordance with an aspect of the disclosure, a memory is provided that includes: a sense amplifier having a sense amplifier output node; a latch configured to latch a data-in signal to form a latch data output signal; a first logic gate configured to process the latch data output signal with a scan enable signal to provide a scan-in signal at a first logic gate output node; and a first switch coupled between the first logic gate output node and the sense amplifier output node.

In accordance with another aspect of the disclosure, a method of operating a memory is provided that includes: clocking a clocked latch during a scan operation to the memory to latch a data-in signal to form a latch data output signal; processing the latch data output signal through a first logic gate to form a scan-in signal during the scan operation to the memory; passing the scan-in signal through a first switch to a first output node of a sense amplifier during the scan operation to the memory; preventing a clocking of the clocked latch during a read operation to the memory; opening the first switch during the read operation to the memory; and forcing the first logic gate to maintain the scan-in signal at a constant binary value while the first switch is open during the read operation to the memory.

In accordance with yet another aspect of the disclosure, a memory is provided that includes: a sense amplifier including a sense amplifier output node; a latch configured to latch a data-in signal to form a latch data output signal; a first logic gate configured to process the latch data output signal with a scan enable signal to provide a scan-in signal at a first logic gate output node; and a first transistor coupled between the sense amplifier output node and ground, wherein a gate of the first transistor is coupled to the first logic gate output node.

Finally, in accordance with another aspect of the disclosure, a method of operating a memory is provided that includes: clocking a clocked latch during a scan operation to the memory to latch a data-in signal to form a latch data output signal; processing the latch data output signal through a first logic gate to form a scan-in signal during the scan operation to the memory; controlling whether a first switch coupled between a first output node of a sense amplifier and ground is open or closed responsive to a binary value of the scan-in signal during the scan operation to the memory; preventing a clocking of the clocked latch during a read operation to the memory; and forcing the first logic gate to maintain the scan-in signal at a constant binary value to keep the first switch open during the read operation to the memory.

These and other advantageous features may be better appreciated through the following detailed description.

### BRIEF DESCRIPTION OF THE DRAWINGS

FIG. 1 is a circuit diagram of a memory including a scan path in which a blocking logic gate couples between a data-in latch and a scan-in switch transistor to a sense amplifier output node in accordance with an aspect of the disclosure.

FIG. 2 is a circuit diagram of a memory including a scan path in which a blocking logic gate couples between a data-in latch and a gate of a scan-in switch transistor coupled to a sense amplifier output node in accordance with an aspect of the disclosure.

FIG. 3 is a flowchart of an example method of operation for a memory in accordance with an aspect of the disclosure.

FIG. 4 illustrates some example electronic systems including a memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

In a static random-access memory (SRAM), each bitcell is formed by a pair of cross-coupled inverters. A first inverter in the cross-coupled pair drives a bit line whereas a remaining second inverter drives a complement bit line. The bitcells are typically arranged in rows according to word lines and in columns according to bit line pairs. Each bit line pair includes a bit line and a complement bit line and traverses a corresponding column of bitcells. Prior to a read operation, the bit line pairs are pre-charged such as to a memory power supply voltage. A word line voltage for an accessed row of bitcells is then asserted. Depending upon the binary content of the bitcell, each accessed bitcell will then start to discharge one of the pre-charged bit lines in the corresponding bit line pair. Each bit line pair may then be sensed by a corresponding sense amplifier. The sense amplifier makes a bit decision based upon detecting which bit line in the corresponding bit line pair remained charged and which bit line was discharged during the read operation.

As compared to a dynamic random-access memory in which the bitcell uses a passive capacitor for storing a bit, the cross-coupled inverters in an SRAM bitcell drive their respective bit lines so that the associated sense amplifier may make a bit decision relatively quickly. The resulting speed of SRAM makes SRAM a popular choice for an embedded memory in integrated circuit design. A modern SoC may thus have thousands of embedded SRAMs such that the embedded SRAMs dominate the chip area. Given the importance of embedded memories to SoC design, it is desirable that a memory designer provide a scan path to the memory so that the operation of peripheral logic components such as the read path may be verified.

In a scan of the peripheral logic of a memory, the timing of the scan should mimic the functional timing of the memory. To do so, the scan path may include the sense amplifier. Prior to the scan operation, a scan-in bit signal is latched in a clocked data in (Din) latch that is also used to latch the data in bit signal during a normal write operation. Since both the bit line and the complement bit line are driven in a complementary fashion during both a scan operation and a write operation, the Din latch produces both a latch output signal and a complement latch output signal. Prior to the triggering clock edge, the Din latch is transparent such that its latch output signals vary according to the binary value of the data in signal (for brevity, both the scan-in signal received by the Din latch during a scan mode of operation and the data-in signal received by the Din latch during a write operation will be simply denoted as the “data-in” signal since the same Din latch is used for both operations). But after the triggering clock edge, the Din latch is closed such that it will not change its output signals despite any binary transitions of the data in signal. The clocking of the Din latch involves the switching of transistors within the Din latch such that the clocking operation consumes power. To reduce power consumption, it is thus beneficial that the Din latch is not clocked during a read operation. Instead, the Din latch may be clocked only during write operations and scan operations.

The transparency of the Din latch when it is not clocked raises an issue during a read operation since the scan path will pass through the sense amplifier so that the functional mode timing is mimicked. In particular, there are a pair of scan-in switches that allow the coupling of the Din latch to the bit line pair during a scan operation and that isolate the Din latch from the bit line pair during a read operation. Each scan-in switch may be formed by a corresponding metal-oxide-semiconductor-field-effect transistor (MOSFET). There is thus a first MOSFET that functions as a first scan-in switch between a node for the latch output signal from the Din latch and the bit line. Similarly, a second MOSFET functions as a second scan-in switch between a node for the complement latch output signal from the Din latch and the complement bit line. Each MOSFET is off during the read operation so as to isolate the Din latch from the bit line pair. But this isolation is not perfect, there is a drain-to-source (and source-to-drain) coupling across the MOSFET despite the MOSFET being switched off. It is possible that the data-in signal will toggle (have a binary transition) during a read operation. For example, the data-in signal may be toggled during a read operation in anticipation of an upcoming write operation. This toggling of the data-in signal causes both the latch output signal and the complement latch output signal to each have a corresponding binary transition since the Din latch is not clocked during a read operation. These binary transitions may then couple across the respective scan-in switches to affect the bit line voltages during the read operation.

The resulting coupling affects the offset margin the sense amplifier needs to make a bit decision. This offset is the voltage difference that develops between the bit lines in the bit line pair during a read operation so that the sense amplifier can make a bit decision. Recall that the bit lines are pre-charged prior to the read operation. At the start of the read operation, the voltage difference between the bit lines is thus zero volts. But as the read operation progresses, the accessed bitcell will begin discharging one of the bit lines from this pre-charged state. Once the bit lines have developed a sufficient voltage offset, the sense amplifier is activated through a sense enable signal to perform the bit sensing so that a data output signal (and a complement data output signal) may be sensed. The smaller the offset, the faster the read operation can be accomplished. The offset thus has a direct bearing on the memory speed.

The coupling from the toggling of the data-in signal and the resulting toggling of the latch output signal and the complement latch output signal produces some finite voltage difference (e.g., 5 mV although this will depend upon the process node and other factors) across the sense amplifier output nodes during the read operation. The offset for the sense amplifier must then be sufficiently greater than this voltage difference or the bit decision may be polluted by the coupling to the toggling of the data-in signal. The greater the offset, the slower is the resulting memory speed. An alternative to increase the memory speed would be to clock the Din latch during the read operation to prevent it from toggling the latch output signal and the complement latch output signal during the read operation. But this clocking then consumes power. An advantageous memory with scan capture is thus provided in which the Din latch is not clocked during the read operation yet there is no coupling across the scan-in switches. Some implementations of this memory will now be discussed in more detail.

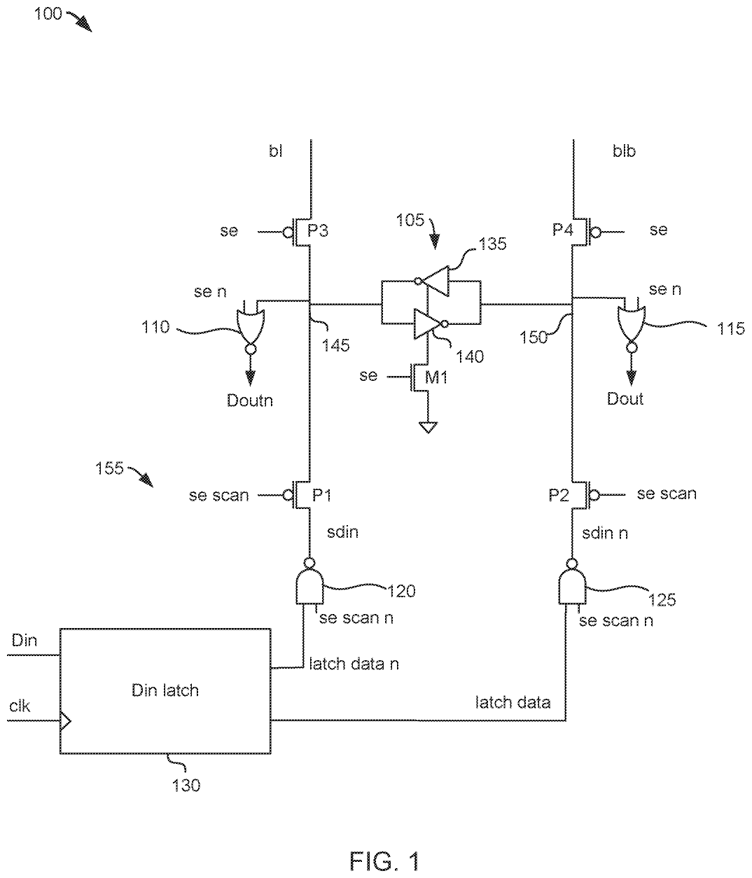

An example memory 100 is shown in FIG. 1. A bit line (bl) and a complement bit line (blb) form a bit line pair that is sensed by a sense amplifier 105 during a read operation. The sense amplifier 105 senses the bit lines through a sense amplifier output node 145 and a complement sense amplifier output node 150. Prior to the assertion of an active-high sense enable signal, the sense amplifier output nodes 145 and 150 are coupled to the bit lines. Thus, as the bit line voltage difference develops during an initial portion of a read operation, the same voltage difference develops across the sense amplifier output nodes 145 and 150. As used herein, a binary signal is deemed to be asserted when the signal is true, regardless of whether the signal is active-low or active-high. An active-high signal such as the sense enable signal is thus asserted by being charged to a power supply voltage. In contrast, an active-low signal is deemed to be asserted herein when the active-low signal is discharged.

The sense amplifier output node 145 couples to the bit line (bl) through a p-type metal-oxide semiconductor (PMOS) transistor P3. Similarly, the complement sense amplifier output node 150 couples to the complement bit line through a PMOS transistor P4. The sense enable signal drives the gates of transistors P3 and P4. Prior to the assertion of the sense amplifier signal, both transistors P3 and P4 are thus on so that the sense amplifier output node 145 is coupled to the bit line and so that the complement sense amplifier output node 150 is coupled to the complement bit line. At the assertion of the sense enable signal, both transistors P3 and P4 switch off to isolate the sense amplifier output nodes 145 and 150 from their respective bit lines.

The sense amplifier 105 is formed by a pair of cross coupled inverters although it will be appreciated that other sense amplifier implementations may be used. A first inverter 135 functions to invert a voltage of the complement sense amplifier output node 150 to drive the sense amplifier output node 145. Similarly, a second inverter 140 inverts a voltage of the sense amplifier output node 145 to drive the complement sense amplifier output node 150. A ground node for each inverter 135 and 140 couples to ground through an n-type metal-oxide-semiconductor (NMOS) transistor M1. The sense enable signal drives the gate of transistor M1 so that the sense amplifier 105 is enabled in response to an assertion of the sense enable signal. When enabled, the sense amplifier 105 functions to amplify the voltage difference between the sense amplifier output nodes 145 and 150 until one of the nodes is grounded and the other is charged to the memory power supply voltage difference.

This amplification by the sense amplifier 105 may occur both during a read operation and during a scan operation. In both cases, the bit lines are pre-charged to the memory power supply voltage prior to the assertion of the sense enable signal. A pair of PMOS scan-in switch transistors P1 and P2 complete a scan path 155 to the sense amplifier output nodes 145 and 150. Scan-in switch transistor P1 transistor couples between the sense amplifier output node 145 and a node for a scan-in signal (sdin) from the scan path 155. Similarly, scan-in switch transistor P2 couples between the complement sense amplifier output node 150 and a node for a complement scan-in signal (sdin n) from the scan path 155. An active-low scan enable signal (se scan) drives the gates of the scan-in switch transistors P1 and P2 so that these transistors are off during a read or write operation. The scan enable signal is asserted during a scan operation. Since it is active-low, the scan enable signal is asserted during a scan operation by being discharged. The scan-in switch transistors are thus on during a scan operation. Conversely, the scan enable signal is charged to the memory power supply voltage so that the scan-in switch transistors P1 and P2 are off during a read operation.

Scan path 155 (which may also be denoted as a scan capture circuit) includes a clocked Din latch 130 that receives the data-in signal. During a scan operation, a clock signal (clk) clocks the Din latch 130 so that the data-in signal (Din) is latched. But during a read operation, the clock signal does not clock the Din latch. Based upon the latched bit, the Din latch 130 drives a latch data output signal (latch data) and a complement latch data signal (latch data n) accordingly. For example, if the latched bit is a binary one, then the latch data output signal is charged to the power supply voltage whereas the complement latch data signal is discharged to ground. These latched output signals will not change while the sense enable signal is asserted during the scan mode of operation since the Din latch 130 is clocked so as to be closed prior to the assertion of the sense enable signal. But during a read operation, the Din latch 130 remains transparent since it is not clocked. The latch output signals can then toggle (have a binary transition) in response to a toggling of the data-in signal. To prevent this toggling from affecting the offset for the sense amplifier 105, the scan path 155 includes a pair of blocking logic gates such as a NAND gate 120 and a NAND gate 125. NAND gate 125 NANDs the latch data output signal with a complement (se scan n) of the scan enable signal. Similarly, the NAND gate 120 NANDs the complement latch data output signal with the complement of the scan enable signal (se scan n). It will be appreciated that the complement of the scan enable signal may instead be denoted as a scan enable signal such that it would be the scan-in switch transistors P1 and P2 that receive a complement of such a signal. Since the scan enable signal is active-low, the complement of the scan enable signal will be charged to the memory power supply voltage during a scan operation. Conversely, the complement of the scan enable signal will be discharged to ground during a read operation. An output signal of at a logic gate output node of NAND gate 120 and an output signal at a logic gate output node of NAND gate 125 will thus both be charged to the memory power supply voltage during a read operation. The output signal of NAND gate 120 is the scan-in signal sdin whereas the output signal of the NAND gate 125 is a complement scan-in signal (sdin n). The processing of the complement of the scan enable signal in NAND gates 120 and 125 thus prevents the toggling of the data input signal to the Din latch 130 from affecting the read operation. In particular, the scan-in signal sdin and the complement scan-in signal sdin n will both be prevented from toggling despite any toggling of the data-in signal to the Din latch 130 during a read operation. There is thus no coupling across the scan-in switch transistors P1 and P2 that will affect the sensing by the sense amplifier 105 during a read operation. It will be appreciated that other types of logic gates could be used in scan path 155 to perform this blocking of the data input signal toggling from affecting the sensing by sense amplifier 105.

During a scan operation, the scan enable signal is asserted low so that the scan-in switch transistors P1 and P2 are switched on. Should the latch data output signal be a binary one due to the data-in signal being a binary one during a scan operation, the complement scan-in signal from NAND gate 125 will be a binary zero, which forces the complement sense amplifier output node 150 to be binary zero also. Conversely, the scan-in signal from NAND gate 120 would then be a binary one (assuming an active-high convention), which forces the sense amplifier output node 145 to also be a binary one. This binary values are then reinforced by the action of the sense amplifier 105 when the sense enable signal is asserted. To read out the results of the scan operation (or a read operation), a NOR gate 115 NORs the voltage of the complement sense amplifier output node 150 with the complement sense enable signal (se n) to produce a data out (Dout) signal. For example, if the complement sense amplifier output node 150 is discharged during a scan operation, the Dout signal will then be a binary one, which is to be expected since it would be in response to the Din signal being a binary one. Conversely, if the Din signal is a binary zero during a scan operation, the Dout signal will also be a binary zero.

Similarly, a NOR gate 110 NORs the voltage of the sense amplifier output node 145 with the complement sense enable signal to produce a complement data out (Doutn) signal. For example, if the sense amplifier output node 145 is discharged during a scan operation, the Doutn signal will then be a binary one, which is to be expected since it would be in response to the Din signal being a binary zero. Conversely, if the Din signal is a binary one during a scan operation, the Doutn signal will be a binary zero.

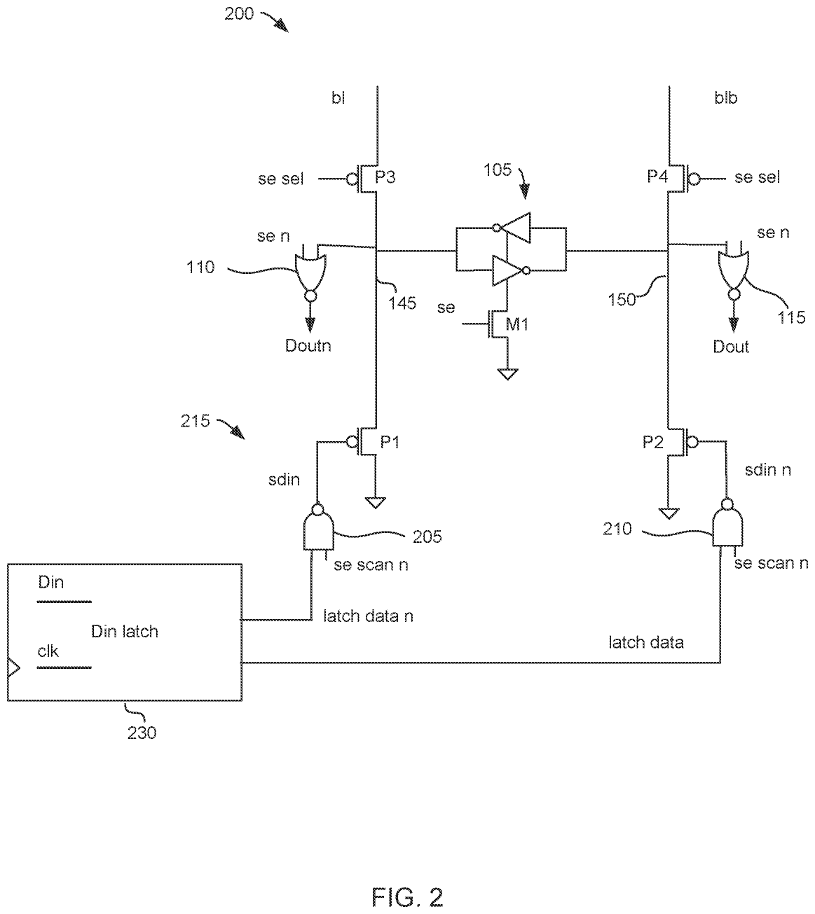

Rather than have the scan-in signals couple through the channel of the scan-in switch transistors P1 and P2, the output signals of the blocking logic gates may drive the gate of these transistors in alternative implementations. An example memory 200 is shown in FIG. 2 in which the gate of the scan-in transistors P1 and P2 are driven by the output signals of the blocking logic gates in a scan path 215. Apart from the scan path 215, the remainder of memory 200 is as discussed with regard to memory 100. In scan path 215, a Din latch 230 is clocked during a scan operation so that it latches the Din signal to form the latch output signal and the complement of the latch output signal as discussed analogously for scan path 155. The blocking logic gates that function to prevent the togging of the Din signal from affecting a read operation are formed by a pair of NAND gates 205 and 210 but it will be appreciated that other types of logic gates may be used to perform this blocking function. The NAND gate 210 NANDs the latch data output signal with the complement scan enable signal (se scan n) to produce a complement scan-in signal (sdin n) that drives the gate of the scan-in switch transistor P2. The drain of the scan-in switch transistor P2 is coupled to ground. The scan-in switch transistor P2 will thus switch on to ground the complement sense amplifier output node 150 during a scan operation if the Din signal is a binary one, which causes the Dout signal from NOR gate 115 to also be a binary one. Similarly, the NAND gate 205 NANDs the complement latch data output signal (latch data n) with the complement scan enable signal (se scan n) to produce a scan-in signal (sdin) that drives the gate of the scan-in switch transistor P1. The drain of the scan-in switch transistor P1 is coupled to ground. The scan-in switch transistor P1 will thus switch on to ground the sense amplifier output node 145 during a scan operation if the Din signal is a binary zero, which causes the Doutn signal from NOR gate 110 to be a binary one.

During a read operation, the Din signal to the Din latch 230 may toggle but NAND gates 205 and 210 prevent this toggling from affecting the operation of the sense amplifier 105. In particular, the complement scan enable signal is a binary zero during the read operation, which forces the sdin and sdin n signals to both be binary ones (charged to the memory power supply voltage), regardless of whether the Din signal toggles or not. Both the scan-in switch transistors P1 and P2 are thus off during a read operation. The toggling of the Din signal during a read operation in memory 200 is thus blocked by NAND gates 205 and 210 from affecting the read operation.

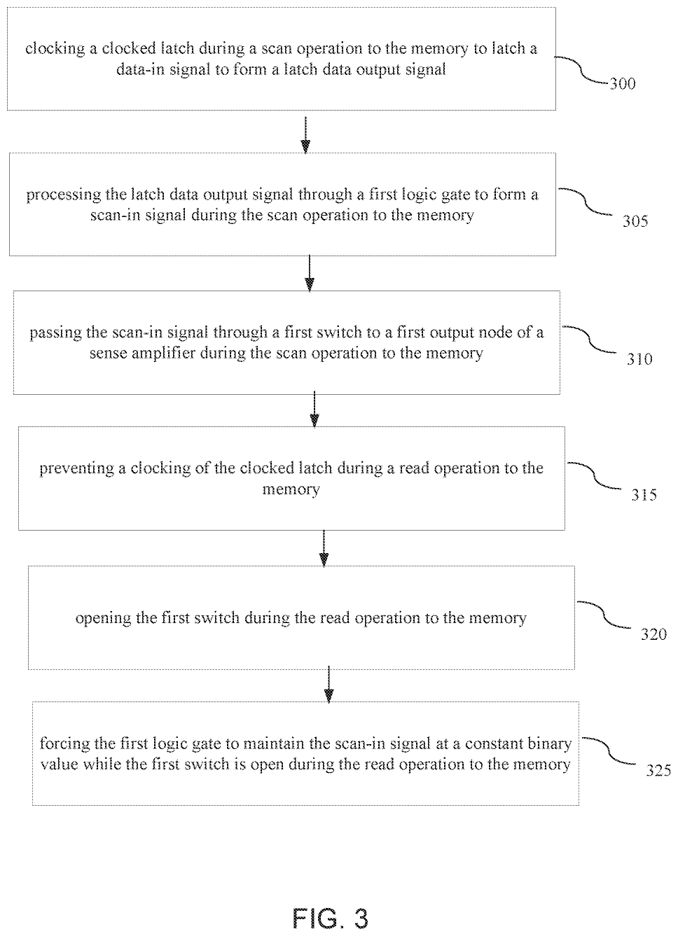

A method of operating a memory with a scan path as disclosed herein will now be discussed with regard to the flowchart of FIG. 3. The method includes an act 300 of clocking a clocked latch during a scan operation to the memory to latch a data-in signal to form a latch data output signal. The clocking of the Din latch 130 is an example of act 300. The method further includes an act 305 of processing the latch data output signal through a first logic gate to form a scan-in signal during the scan operation to the memory. The processing of the latch data output signal through NAND gate 125 is an example of act 305. In addition, the method includes an act 310 of passing the scan-in signal through a first switch to a first output node of a sense amplifier during the scan operation to the memory. The passing of the complement scan-in signal through transistor P2 to the complement sense amplifier output node 150 is an example of act 310. Moreover, the method includes an act 315 of preventing a clocking of the clocked latch during a read operation to the memory. An example of act 315 is memory 100 preventing the clocking of the Din latch 130 during a read operation. The method also includes an act 320 of opening the first switch during the read operation to the memory. The switching off of transistor P2 during a read operation to memory 100 is an example of act 320. Finally, the method includes an act 325 of forcing the first logic gate to maintain the scan-in signal at a constant binary value while the first switch is open during the read operation to the memory. The action of NAND 125 in maintaining the complement scan-in signal constant during a read operation is an example of act 325.

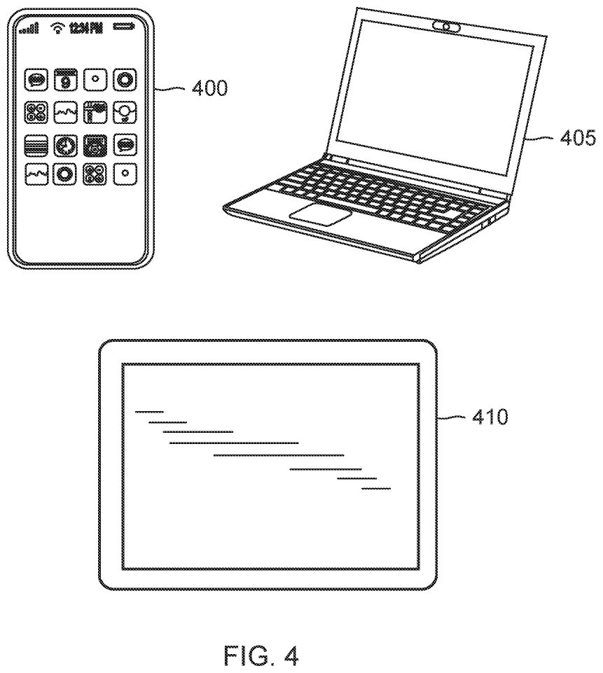

Memories having a scan-in path as disclosed herein advantageously allow the memory to have increased speed due to the reduced offset the sense amplifier needs to make a bit decision during a read operation. A variety of electronic systems will thus benefit from including a memory as disclosed herein. For example, as shown in FIG. 4, a cellular telephone 400, a laptop computer 405, and a tablet PC 410 may all include a memory in accordance with the disclosure. Other exemplary electronic systems such as a music player, a video player, a communication device, and a personal computer may also be configured with a memory constructed in accordance with the disclosure.

The disclosure will now be summarized in the following series of clauses:
Clause 1. A memory, comprising:
   a sense amplifier including a sense amplifier output node;
   a latch configured to latch a data-in signal to form a latch data output signal;
   a first logic gate configured to process the latch data output signal with a scan enable signal to provide a scan-in signal at a first logic gate output node; and
   a first switch coupled between the first logic gate output node and the sense amplifier output node.
Clause 2. The memory of clause 1, wherein the sense amplifier further includes a complement sense amplifier output node, and wherein the latch is further configured to form a complement of the latch data output signal, the memory further comprising:
   a second logic gate configured to process the complement of the latch data output signal with the scan enable signal to provide a complement of the scan-in signal at a second logic gate output node; and
   a second switch coupled between the second logic gate output node and the complement sense amplifier output node.
Clause 3. The memory of any of clauses 1-2, wherein the first logic gate comprises a first NAND gate.
Clause 4. The memory of any of clauses 1-3, wherein the first switch comprises a p-type metal-oxide semiconductor (PMOS) transistor.
Clause 5. The memory of clause 4, wherein a gate of the PMOS transistor is configured to receive a complement of the scan enable signal.
Clause 6. The memory of any of clauses 1-5, wherein the memory is configured to assert the scan enable signal during a scan operation to the memory and to de-assert the scan enable signal during a read operation to the memory.
Clause 7. The memory of any of clauses 1-6, wherein the latch comprises a clocked latch configured to latch the data-in signal responsive to a clock signal.
Clause 8. The memory of clause 7, wherein the memory is configured to clock the clocked latch with the clock signal during a scan operation to the memory and to not clock the clocked latch during a read operation to the memory.
Clause 9. The memory of any of clauses 1-8, wherein the sense amplifier comprises a pair of cross-coupled inverters.
Clause 10. The memory of any of clauses 1-9, wherein the memory is included within a cellular telephone.
Clause 11. A method of operating a memory, comprising:
   clocking a clocked latch during a scan operation to the memory to latch a data-in signal to form a latch data output signal;
   processing the latch data output signal through a first logic gate to form a scan-in signal during the scan operation to the memory;
   passing the scan-in signal through a first switch to a first output node of a sense amplifier during the scan operation to the memory;
   preventing a clocking of the clocked latch during a read operation to the memory;
   opening the first switch during the read operation to the memory; and
   forcing the first logic gate to maintain the scan-in signal at a constant binary value while the first switch is open during the read operation to the memory.
Clause 12. The method of clause 11, further comprising:
   processing a complement of the latch data output signal through a second logic gate to form a complement of the scan-in signal during the scan operation to the memory;
   passing the complement of the scan-in signal through a second switch to a second output node of the sense amplifier during the scan operation to the memory;
   opening the second switch during the read operation to the memory; and
   forcing the second logic gate to maintain the complement of the scan-in signal at a constant binary value while the second switch is open during the read operation to the memory.
Clause 13. The method of any of clauses 11-12, wherein processing the latch data output signal through the first logic gate to form the scan-in signal during the scan operation to the memory comprises processing the latch data output signal with a scan enable signal in a NAND gate.
Clause 14. The method of clause 13, further comprising:
   asserting the scan enable signal during the scan operation to the memory; and
   de-asserting the scan enable signal during the read operation to the memory.
Clause 15. The method of any of clauses 11-14, wherein forcing the first logic gate to maintain the scan-in signal at a constant binary value while the first switch is open during the read operation to the memory comprises keeping the scan-in signal charged to a memory power supply voltage.
Clause 16. A memory, comprising:
   a sense amplifier including a sense amplifier output node;
   a latch configured to latch a data-in signal to form a latch data output signal;
   a first logic gate configured to process the latch data output signal with a scan enable signal to provide a scan-in signal at a first logic gate output node; and
   a first transistor coupled between the sense amplifier output node and ground, wherein a gate of the first transistor is coupled to the first logic gate output node.
Clause 17. The memory of clause 16, wherein the sense amplifier further includes a complement sense amplifier output, and wherein the latch is further configured to form a complement of the latch data output signal, the memory further comprising:
   a second logic gate configured to process the complement of the latch data output signal with the scan enable signal to provide a complement of the scan-in signal at a second logic gate output node; and
   a second transistor coupled between the complement sense amplifier output node and the ground, wherein a gate of the second transistor is coupled to the second logic gate output node.
Clause 18. The memory of any of clauses 16-17, wherein the first logic gate comprises a first NAND gate.
Clause 19. The memory of any of clauses 16-18, wherein the first transistor comprises a first PMOS transistor.
Clause 20. The memory of any of clauses 16-19, wherein the memory is configured to assert the scan enable signal during a scan operation to the memory and to de-assert the scan enable signal during a read operation to the memory.
Clause 21. The memory of any of clauses 16-20, wherein the latch comprises a clocked latch configured to latch the data-in signal responsive to a clock signal.
Clause 22. The memory of clause 21, wherein the memory is configured to clock the clocked latch with the clock signal during a scan operation to the memory and to not clock the clocked latch during a read operation to the memory.
Clause 23. The memory of any of clauses 16-22, wherein the memory is included within a cellular telephone.
Clause 24. A method of operating a memory, comprising:
   clocking a clocked latch during a scan operation to the memory to latch a data-in signal to form a latch data output signal;
   processing the latch data output signal through a first logic gate to form a scan-in signal during the scan operation to the memory;
   controlling whether a first switch coupled between a first output node of a sense amplifier and ground is open or closed responsive to a binary value of the scan-in signal during the scan operation to the memory;
   preventing a clocking of the clocked latch during a read operation to the memory; and
   forcing the first logic gate to maintain the scan-in signal at a constant binary value to keep the first switch open during the read operation to the memory.
Clause 25. The method of clause 24, further comprising:
   processing a complement of the latch data output signal through a second logic gate to form a complement of the scan-in signal during the scan operation to the memory;
   controlling whether a second switch coupled between a second output node of the sense amplifier and ground is open or closed responsive to a binary value of the complement of the scan-in signal during the scan operation to the memory; and
   forcing the second logic gate to maintain the complement of the scan-in signal at a constant binary value to keep the second switch open during the read operation to the memory.
Clause 26. The method of clause 24, wherein processing the latch data output signal through the first logic gate to form the scan-in signal during the scan operation to the memory comprises processing the latch data output signal with a scan enable signal in a NAND gate.
Clause 27. The method of clause 26, further comprising:
   asserting the scan enable signal during the scan operation to the memory; and
   de-asserting the scan enable signal during the read operation to the memory.
Clause 28. The method of clause 27, wherein forcing the first logic gate to maintain the scan-in signal at the constant binary value to keep the first switch open during the read operation to the memory comprises forcing the first logic gate to keep the scan-in signal charged to a memory power supply voltage.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A memory, comprising:
a sense amplifier including a sense amplifier output node;
a latch configured to latch a data-in signal to form a latch data output signal;
a first logic gate configured to process the latch data output signal with a scan enable signal to provide a scan-in signal at a first logic gate output node; and
a first switch coupled between the first logic gate output node and the sense amplifier output node.

2. The memory of claim 1, wherein the sense amplifier further includes a complement sense amplifier output node, and wherein the latch is further configured to form a complement of the latch data output signal, the memory further comprising:
a second logic gate configured to process the complement of the latch data output signal with the scan enable signal to provide a complement of the scan-in signal at a second logic gate output node; and
a second switch coupled between the second logic gate output node and the complement sense amplifier output node.

3. The memory of claim 1, wherein the first logic gate comprises a first NAND gate.

4. The memory of claim 1, wherein the first switch comprises a p-type metal-oxide semiconductor (PMOS) transistor.

5. The memory of claim 4, wherein a gate of the PMOS transistor is configured to receive a complement of the scan enable signal.

6. The memory of claim 1, wherein the memory is configured to assert the scan enable signal during a scan operation to the memory and to de-assert the scan enable signal during a read operation to the memory.

7. The memory of claim 1, wherein the latch comprises a clocked latch configured to latch the data-in signal responsive to a clock signal.

8. The memory of claim 7, wherein the memory is configured to clock the clocked latch with the clock signal during a scan operation to the memory and to not clock the clocked latch during a read operation to the memory.

9. The memory of claim 1, wherein the sense amplifier comprises a pair of cross-coupled inverters.

10. The memory of claim 1, wherein the memory is included within a cellular telephone.

11. A method of operating a memory, comprising:
clocking a clocked latch during a scan operation to the memory to latch a data-in signal to form a latch data output signal;
processing the latch data output signal through a first logic gate to form a scan-in signal during the scan operation to the memory;
passing the scan-in signal through a first switch to a first output node of a sense amplifier during the scan operation to the memory;
preventing a clocking of the clocked latch during a read operation to the memory;
opening the first switch during the read operation to the memory; and
forcing the first logic gate to maintain the scan-in signal at a constant binary value while the first switch is open during the read operation to the memory.

12. The method of claim 11, further comprising:
processing a complement of the latch data output signal through a second logic gate to form a complement of the scan-in signal during the scan operation to the memory;
passing the complement of the scan-in signal through a second switch to a second output node of the sense amplifier during the scan operation to the memory;
opening the second switch during the read operation to the memory; and
forcing the second logic gate to maintain the complement of the scan-in signal at a constant binary value while the second switch is open during the read operation to the memory.

13. The method of claim 11, wherein processing the latch data output signal through the first logic gate to form the scan-in signal during the scan operation to the memory comprises processing the latch data output signal with a scan enable signal in a NAND gate.

14. The method of claim 13, further comprising:
asserting the scan enable signal during the scan operation to the memory; and
de-asserting the scan enable signal during the read operation to the memory.

15. The method of claim 11, wherein forcing the first logic gate to maintain the scan-in signal at a constant binary value while the first switch is open during the read operation to the memory comprises keeping the scan-in signal charged to a memory power supply voltage.

16. A memory, comprising:
a sense amplifier including a sense amplifier output node;
a latch configured to latch a data-in signal to form a latch data output signal;
a first logic gate configured to process the latch data output signal with a scan enable signal to provide a scan-in signal at a first logic gate output node; and
a first transistor coupled between the sense amplifier output node and ground, wherein a gate of the first transistor is coupled to the first logic gate output node.

17. The memory of claim 16, wherein the sense amplifier further includes a complement sense amplifier output, and wherein the latch is further configured to form a complement of the latch data output signal, the memory further comprising:
a second logic gate configured to process the complement of the latch data output signal with the scan enable signal to provide a complement of the scan-in signal at a second logic gate output node; and
a second transistor coupled between the complement sense amplifier output node and the ground, wherein a gate of the second transistor is coupled to the second logic gate output node.

18. The memory of claim 16, wherein the first logic gate comprises a first NAND gate.

19. The memory of claim 16, wherein the first transistor comprises a first PMOS transistor.

20. The memory of claim 16, wherein the memory is configured to assert the scan enable signal during a scan operation to the memory and to de-assert the scan enable signal during a read operation to the memory.

21. The memory of claim 16, wherein the latch comprises a clocked latch configured to latch the data-in signal responsive to a clock signal.

22. The memory of claim 21, wherein the memory is configured to clock the clocked latch with the clock signal during a scan operation to the memory and to not clock the clocked latch during a read operation to the memory.

23. The memory of claim 16, wherein the memory is included within a cellular telephone.

24. A method of operating a memory, comprising:
clocking a clocked latch during a scan operation to the memory to latch a data-in signal to form a latch data output signal;
processing the latch data output signal through a first logic gate to form a scan-in signal during the scan operation to the memory;
controlling whether a first switch coupled between a first output node of a sense amplifier and ground is open or closed responsive to a binary value of the scan-in signal during the scan operation to the memory;
preventing a clocking of the clocked latch during a read operation to the memory; and
forcing the first logic gate to maintain the scan-in signal at a constant binary value to keep the first switch open during the read operation to the memory.

25. The method of claim 24, further comprising:
processing a complement of the latch data output signal through a second logic gate to form a complement of the scan-in signal during the scan operation to the memory;
controlling whether a second switch coupled between a second output node of the sense amplifier and ground is open or closed responsive to a binary value of the complement of the scan-in signal during the scan operation to the memory; and
forcing the second logic gate to maintain the complement of the scan-in signal at a constant binary value to keep the second switch open during the read operation to the memory.

26. The method of claim 24, wherein processing the latch data output signal through the first logic gate to form the scan-in signal during the scan operation to the memory comprises processing the latch data output signal with a scan enable signal in a NAND gate.

27. The method of claim 26, further comprising:
asserting the scan enable signal during the scan operation to the memory; and
de-asserting the scan enable signal during the read operation to the memory.

28. The method of claim 27, wherein forcing the first logic gate to maintain the scan-in signal at the constant binary value to keep the first switch open during the read operation to the memory comprises forcing the first logic gate to keep the scan-in signal charged to a memory power supply voltage.
